(19) United States
(12) Patent Application Publication
(10) Pub. No.: US 2014/0368186 A1
(43) Pub. Date: Dec. 18, 2014

(54) INSPECTION APPARATUS AND INSPECTION METHOD

(71) Applicant: KABUSHIKI KAISHA TOSHIBA, Tokyo (JP)

(72) Inventor: Takahiro IKEDA, Yokohama-Shi (JP)

(73) Assignee: KABUSHIKI KAISHA TOSHIBA, Tokyo (JP)

(21) Appl. No.: 14/109,575

(22) Filed: Dec. 17, 2013

(30) Foreign Application Priority Data
Jun. 17, 2013 (JP) 2013-126841

(51) Int. Cl. H01J 37/26; G01N 27/00

(52) U.S. Cl. CPC H01J 37/265; G01N 27/00
USPC 324/96; 250/310

(57) ABSTRACT

In accordance with an embodiment, an inspection apparatus includes an electron beam applying unit, a voltage applying unit, a substantially flat component with a lattice pattern, and a first detector. The electron beam applying unit generates an electron beam and applies the electron beam to a sample at a first voltage. The voltage applying unit applies a second voltage to the sample. The polarity of the second voltage is opposite to that of the first voltage. The absolute value of the second voltage exceeds the absolute value of the first voltage. The component is provided at a position where the electron beam specularly reflected by the second voltage before reaching the sample is focused. The first detector detects a secondary electron generated from the component which the specularly reflected electron beam has entered and outputs a first signal.

### CROSS REFERENCE TO RELATED APPLICATIONS

This application is based upon and claims the benefit of priority from the prior Japanese Patent Application No. 2013-126841, filed on Jun. 17, 2013, the entire contents of which are incorporated herein by reference.

### FIELD

Embodiments described herein relate generally to an inspection apparatus and an inspection method.

### BACKGROUND

Along with progress in the miniaturization of semiconductor integrated circuits, defects and particles that may cause an adverse effect on yield have been decreasing in size and becoming extremely difficult to detect. Accordingly, various inspection methods that use high-resolution electron beam optical systems have been suggested.

An inspection method using a mirror optical system is one of such inspection methods. The mirror optical system is a technique for monitoring a spatial distribution of sample surface potentials by applying, to an observation sample, an electric field which is reverse in polarity to an accelerating voltage of a primary electron beam and slightly exceeds the accelerating voltage in absolute value. According to this monitoring technique, a reflection direction is determined in such a manner that the gradient of an equipotential surface of the surface potentials is increased when the primary electron beam is bounced off the sample surface. It is therefore possible to highly sensitively detect a distribution of the surface potentials induced by minute surface defects.

However, according to the conventional inspection method, a pattern image may greatly vary with the variation of a focus position in the case of a high-throughput technique, whereas throughput is lower in the case of a high-precision technique. There have not yet been suggested any technique that satisfies both inspection precision and throughput.

### BRIEF DESCRIPTION OF THE DRAWINGS

In the accompanying drawings:

FIG. 1 is a block diagram showing the general configuration of an inspection apparatus according to Embodiment 1;

FIG. 2 is a diagram illustrating the detection of a secondary electron by the inspection apparatus in FIG. 1;

FIG. 3A is a diagram showing an example of an ideal lattice image;

FIG. 3B is a diagram showing an example of an acquired distorted lattice image;

FIG. 3C is a diagram showing an example of vector quantities representing a landing error of an electron beam specularly reflected by an equipotential surface;

FIG. 3D is a diagram showing an example of an obtained potential distribution;

FIG. 3E is a diagram showing a grayscale image transformed from the example shown in FIG. 3D;

FIG. 4 is a diagram illustrating a method of finding a landing site of a mirror electron when the equipotential surface has a gradient;

FIG. 5 is a block diagram showing the general configuration of an inspection apparatus according to Embodiment 2;

FIG. 6 is a block diagram showing the general configuration of an inspection apparatus according to Embodiment 3;

FIG. 7 is a block diagram showing the general configuration of an inspection apparatus according to Embodiment 4;

FIG. 8 is a block diagram showing the general configuration of an inspection apparatus according to Embodiment 5;

FIG. 9 is a block diagram showing the general configuration of an inspection apparatus according to Embodiment 6;

FIG. 10 is a flowchart showing a general procedure of an inspection method according to Embodiment 1;

FIG. 11 is a flowchart showing a specific procedure of locus information acquisition shown in FIG. 10; and

FIG. 12 is a flowchart showing a general procedure of an inspection method according to Embodiment 2.

### DETAILED DESCRIPTION

In accordance with an embodiment, an inspection apparatus includes an electron beam applying unit, a voltage applying unit, a substantially flat component with a lattice pattern, and a first detector. The electron beam applying unit generates an electron beam and applies the electron beam to a sample at a first voltage. The voltage applying unit applies a second voltage to the sample. The polarity of the second voltage is opposite to that of the first voltage. The absolute value of the second voltage exceeds the absolute value of the first voltage. The component is provided at a position where the electron beam specularly reflected by the second voltage before reaching the sample is focused. The first detector detects a secondary electron generated from the component which the specularly reflected electron beam has entered and outputs a first signal.

Embodiments will now be explained with reference to the accompanying drawings. Like components are provided with like reference signs throughout the drawings and repeated descriptions thereof are appropriately omitted.

### (A) Inspection Apparatus

### (1) Embodiment 1

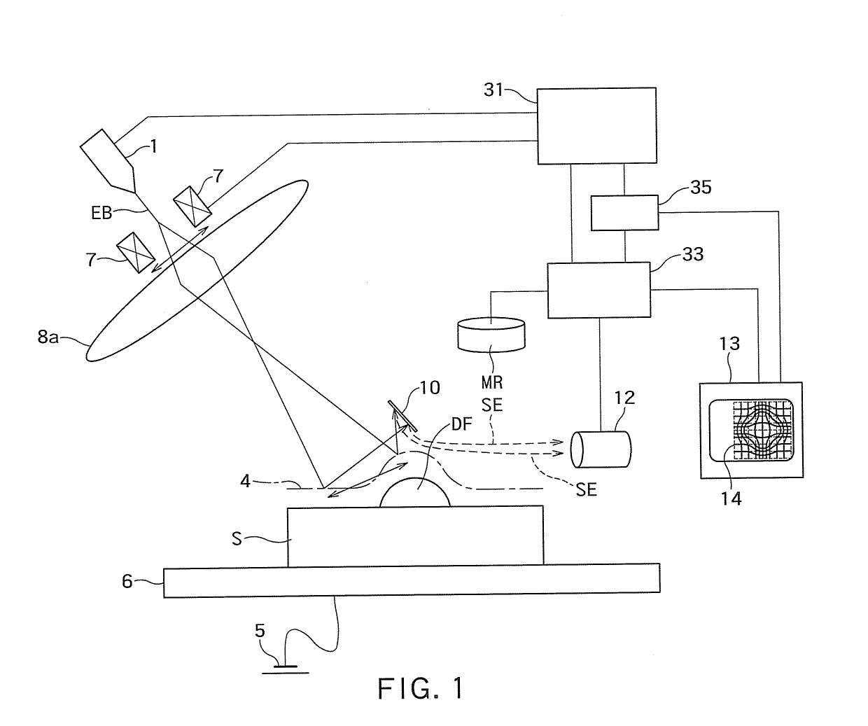

FIG. 1 is a block diagram showing the general configuration of an inspection apparatus according to Embodiment 1. The inspection apparatus according to the present embodiment includes an electron optical system, a voltage source 5, a sample tray 6, a secondary electron generating component 10, a secondary electron detector 12, a potential distribution acquiring unit 33, a control unit 31, a defect inspection unit 35, and a monitor 13. The electron optical system includes an electron gun 1, a deflection coil 7, and electromagnetic lens 8a.

The electron gun 1 generates an electron beam EB when a control signal is inputted from the control unit 31, and the electron gun 1 emits the electron beam EB toward a sample S. The beam flux and the focus position of the electron beam EB are adjusted by the electromagnetic lenses 8a and so forth. The deflection coil 7 is connected to the control unit 31. The deflection coil 7 deflects the electron beam EB when a control signal is inputted to the deflection coil 7 from the control unit 31. Thereby, a desired region on the sample S is scanned with the electron beam EB.

The sample S is held on the upper surface of the sample tray 6. A bias potential is applied to the sample S from the voltage source 5 via the sample tray 6. The polarity of this bias potential is opposite to that of an incoming voltage of the electron beam EB, and the absolute value of the bias potential is set to be higher than the incoming voltage of the electron beam EB. Therefore, the electron beam EB entering toward the sample S is specularly reflected by an equipotential surface 4 located in the vicinity of the sample surface. The specularly reflected electron beam EB then enters a surface of the secondary electron generating component 10 for generating a secondary electron to be detected by the secondary electron detector 12 (hereinafter referred to as the “detection surface”). The focus positions of objective lenses (not shown) are adjusted in such a manner that the electron beam EB from the equipotential surface 4 is just focused on the detection surface of the secondary electron generating component 10.

In the present embodiment, the electron gun 1, the electromagnetic lens 8a, and the deflection coil 7 correspond to, for example, an electron beam applying unit. The voltage source 5 corresponds to, for example, a voltage applying unit. Moreover, in the present embodiment, the incoming voltage of the electron beam EB corresponds to, for example, a first potential, and the bias potential corresponds to, for example, a second potential.

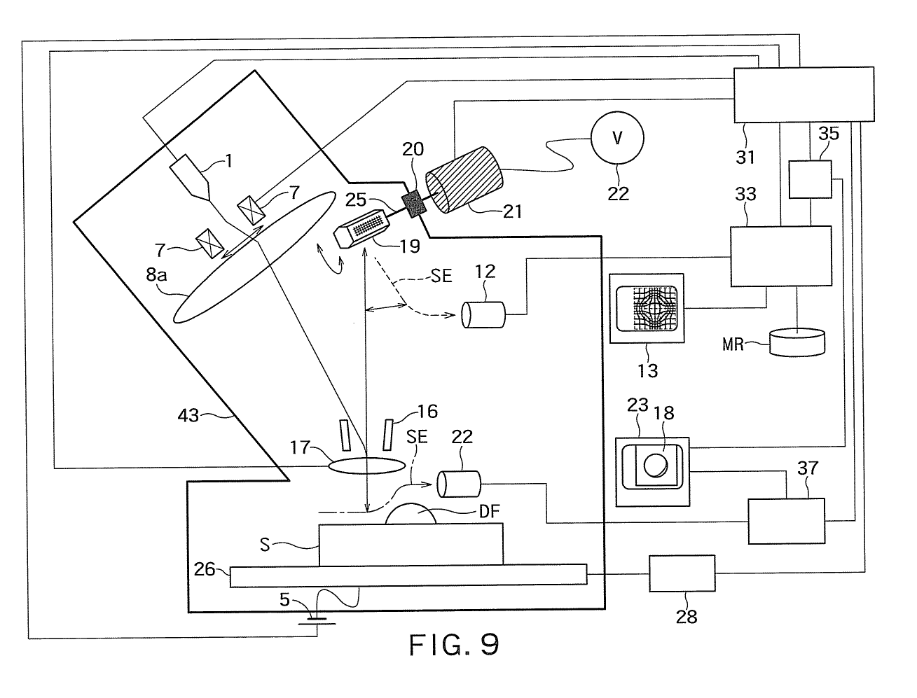

The electron optical system, the sample tray 6, the secondary electron generating component 10, and the secondary electron detector 12 are housed in an unshown vacuum chamber (see the numeral 43 in FIG. 9). This vacuum chamber is connected to an unshown vacuum pump and is thus vacuumized in such a manner that an inspection is conducted in a high-vacuum condition.

A secondary electron SE is emitted from the detection surface of the secondary electron generating component 10 which the electron beam EB has entered.

The secondary electron detector 12 is connected to the potential distribution acquiring unit 33. The secondary electron detector 12 detects the secondary electron SE from the secondary electron generating component 10, and outputs a signal and then sends the signal to the potential distribution acquiring unit 33.

The potential distribution acquiring unit 33 is connected to the secondary electron detector 12, the control unit 31, the defect inspection unit 35, and the display 13. The potential distribution acquiring unit 33 processes the signal from the secondary electron detector 12 to acquire locus information regarding an emission direction of the electron beam EB specularly reflected by the equipotential surface 4 and to cause the display 13 to display the locus information as a lattice image. The potential distribution acquiring unit 33 also acquires a potential distribution in a specular reflection surface of the electron beam EB and then sends the potential distribution to the defect inspection unit 35. A memory MR is connected to the potential distribution acquiring unit 33, and stores information regarding an ideal lattice which will be described in detail later.

The defect inspection unit 35 judges whether the sample S is defective by using the potential distribution information sent from the potential distribution acquiring unit 33. The defect inspection unit 35 outputs information regarding the defect of the sample S by analyzing the number of defects, and the display 13 displays the information. In the example shown in FIG. 1, a distorted lattice image 14 which will be described in detail later is displayed on the display 13.

The control unit 31 is connected to the electron gun 1, the deflection coil 7, the potential distribution acquiring unit 33, and the defect inspection unit 35. The control unit 31 generates a control signal to control these components.

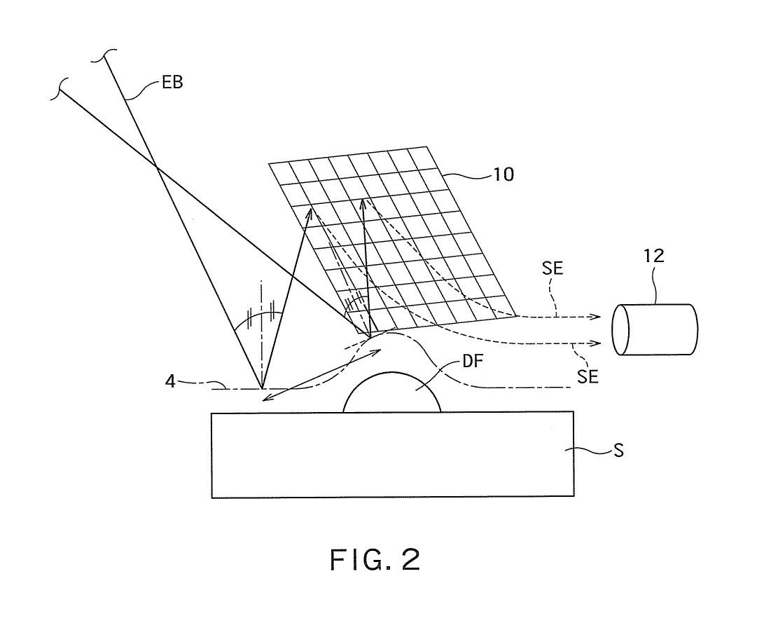

FIG. 2 is an enlarged diagram of essential parts in FIG. 1 including a perspective view of the secondary electron generating component 10. The secondary electron generating component 10 in the present embodiment is formed by an ordered lattice pattern as shown in FIG. 2. In FIG. 2, the equipotential surface 4 is indicated by a chain line, the locus of the electron beam EB is indicated by a solid line, and the locus of the secondary electron is indicated by a dotted line.

The operation of the inspection apparatus shown in FIG. 1 is described with reference to FIG. 2 to FIG. 4.

The deflection coil 7 performs a scan with the electron beam EB which has been generated by the electron gun 1 and which has been emitted toward the sample S, and the electron beam EB is specularly reflected by the equipotential surface 4. The specularly reflected electron beam EB enters the detection surface of the secondary electron generating component 10. The secondary electron SE is emitted from the detection surface. The emitted secondary electron SE is detected by the secondary electron detector 12 and converted to an electric signal, and sent to the potential distribution acquiring unit 33. The potential distribution acquiring unit 33 processes the signal sent from the secondary electron detector 12 to form an image, and displays the image on the display 13 synchronously with the deflection coil 7. As a result, the lattice image 14 (see FIG. 1) formed on the detection surface of the secondary electron generating component 10 by a principle similar to an SEM image formation principle based on a normal scanning electron microscope is displayed.

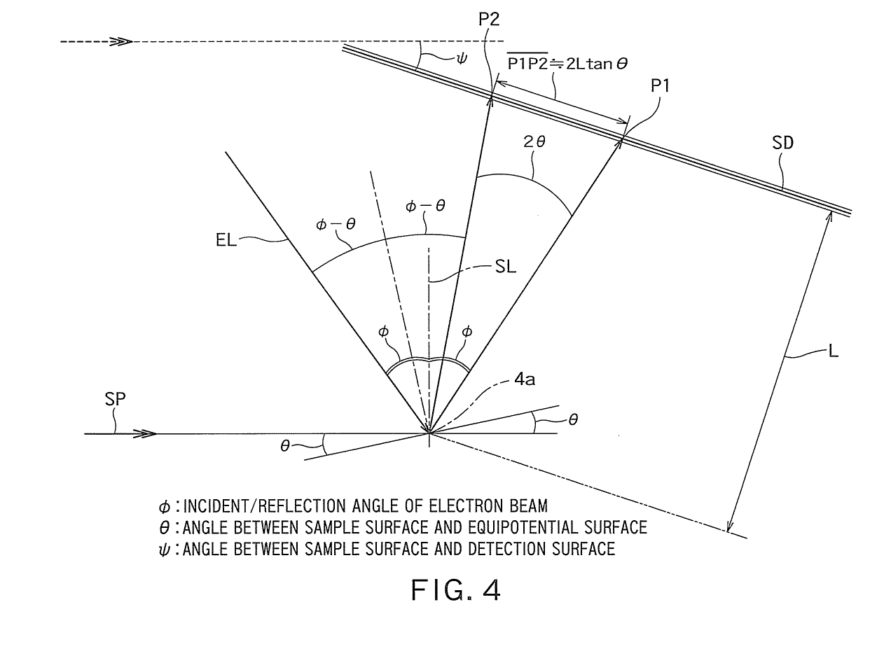

For focus position adjustment during the image formation, it is possible to use a normal autofocus method such that the change of the grayscale value of the lattice image 14 may be sharpest. When the gradient (see θ in FIG. 4) of an equipotential line greatly varies, defocus is caused in the vicinity of the place where a foreign body exists. However, the defocus only blurs line elements constituting the lattice, and hardly affects lattice distortion. Therefore, the central axes of the line elements constituting the lattice have only to be acquired by processing such as thinning after the image acquisition. The focus is not exclusively adjusted after the image acquisition, and may be dynamically adjusted during the scanning of the electron beam EB.

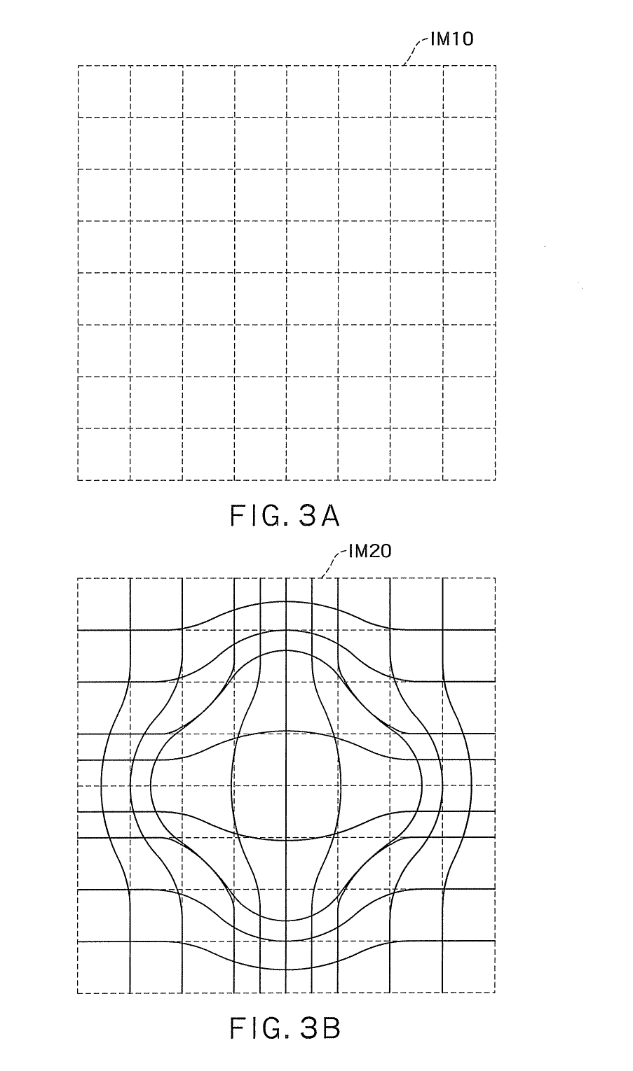

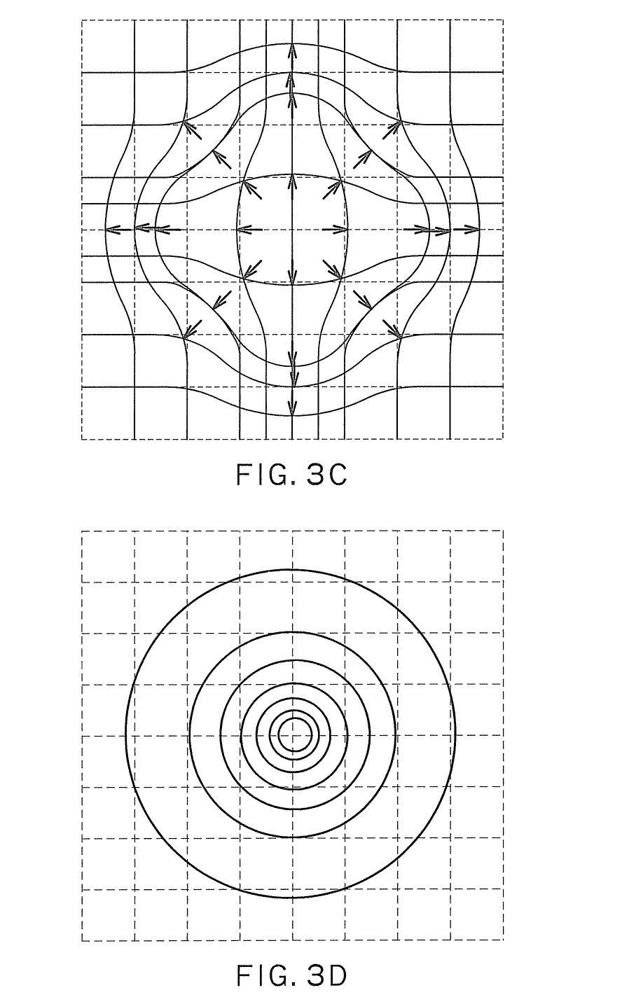

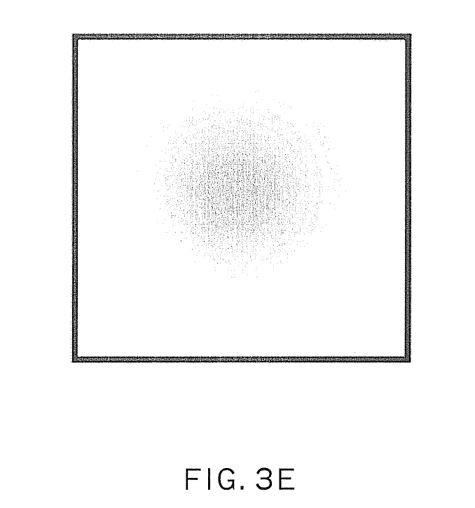

When the surface of the sample S is flat and does not have any defect DF (see FIG. 1) resulting from the foreign body, an undistorted lattice image is formed. An example of such an ideal lattice image is represented by a lattice image IM10 in FIG. 3A.

However, when the surface of the sample S has the defect DF as shown in FIG. 1, the equipotential surface 4 where the specular reflection occurs is not a plane parallel to the sample surface, and has a local gradient depending on the size and shape of the defect DF. Therefore, the emission direction of a primary electron beam specularly reflected in a place having a gradient in the equipotential surface 4 is shifted as compared with that of the primary electron beam reflected in a flat place, and an obtained lattice image is such a distorted lattice image as a lattice image IM20 shown in FIG. 3B.

In connection with the electron beam EB whose emission direction has shifted due to the gradient of the equipotential surface 4, the potential distribution acquiring unit 33 calculates a shift in the landing position of the electron beam EB on the detection surface of the secondary electron generating component 10. Such a shift amount can be found by use of an optical lever principle. An example of this calculation method is described with reference to FIG. 4.

Specifically, as shown in FIG. 4, the detection surface of the secondary electron generating component 10 is referred to as SD. The sample surface of the sample S is referred to as SP. The distance between SD and SP is referred to as L. The gradient of the equipotential surface 4 at a point where the electron beam EB has entered is referred to as θ. Then a landing position P2 of the electron beam EB whose reflection direction has been deflected by θ is shifted by an amount represented by the following equation from an original position P1 in accordance with the optical lever principle:

2L tan θ Equation (1)

Therefore, for example, when L=10 mm and 8=5°, the landing position P2 corresponds to a position which is shifted from the original position on the detection surface SD by 1.7 mm. In order to detect this shift, it is enough to form, for example, a rectangular lattice having a space of about 0.1 mm width on the detection surface SP. In this way, the potential distribution acquiring unit 33 extracts a lattice point from the distorted lattice image IM20 (see FIG. 3B).

The method of producing the secondary electron generating component 10 is as follows. For example, a crystalline silicon flat substrate is used to form an ordered lattice pattern having vertical and horizontal lattice spaces of about 0.1 mm. In this case, a transparent sheet on which a rectangular lattice having an interval of, for example, about 0.1 mm is printed is used as a photomask. The rectangular lattice is projected on a photoactive compound film by use of simple reduction projection exposure equipment. The photoactive compound film is then wet-etched, for example, by an aqueous solution containing tetramethylammonium hydroxide (TMAH) or an aqueous solution containing a hydrofluoric acid and a nitric acid. Consequently, the secondary electron generating component 10 can be easily obtained.

Any substantially flat material can be used as a substrate material to produce the secondary electron generating component 10, and a detection surface can be fabricated thereon. It is possible to properly use a metal having a higher atomic number or its compound, any of which allows a large number of secondary electrons to be obtained. In order to detect minuter or less uneven foreign bodies, it is preferable to form a finer lattice pattern. Various fabrication methods such as dry etching and marking-off can be used depending on a required resolution. It is to be noted that in the present specification, being “substantially flat” means including minute unevenness that does not affect the locus of the secondary electrons generated from the secondary electron generating component 10 and traveling toward the secondary electron detector 12.

After acquiring the distorted lattice image by, for example, the above-mentioned method, the potential distribution acquiring unit 33 superimposes the distorted lattice image on the ideal lattice image to associate the distorted lattice with the ideal lattice. For example, affine transformation of images can be used in the superimposition. In this case, transformation corresponding to a translational operation is conducted to calculate a correlation in such a manner that a large number of lattice points will match. However, when a magnification error or a rotation error is caused by the change in the thickness of the sample, superimposition based on a least squares method is also conducted for this component.

The potential distribution acquiring unit 33 then calculates, as vector quantities, a landing error relative to corresponding positions between the distorted lattice and the ideal lattice. An example of the obtained vector quantities is shown in FIG. 3C. In FIG. 3C, the vector quantities calculated for the corresponding lattices between the lattice image IM10 in

FIG. 3A and the distorted lattice image IM20 in FIG. 3B are represented by arrows.

The potential distribution acquiring unit 33 then calculates, from the obtained vector quantities, a surface potential gradient resulting from one scan with the electron beam EB. This surface potential gradient can be easily calculated if Equation (1) is used in the inverse way, and can be acquired in the form of a function of plane coordinates. The potential distribution acquiring unit 33 sequentially stores, in the memory MR, the surface potential gradient acquired in each scan as described above. After the end of scanning over the whole inspection region, the potential distribution acquiring unit 33 composes the surface potential gradients stored in the memory MR to acquire a potential distribution in the specular reflection surface of the electron beam EB on the surface of the sample S.

FIG. 3D shows contours of the potential distribution obtained from the vector quantities shown in FIG. 3C. As shown in FIG. 3E, the obtained potential distribution can be transformed into a grayscale image as in a normal defect inspection.

The potential distribution information obtained as described above is sent to the defect inspection unit 35 from the potential distribution acquiring unit 33. The defect inspection unit 35 performs processing such as image comparison and counting for the data sent from the potential distribution acquiring unit 33 to acquire information regarding the defect of the sample S, and displays the information on the display 13.

Although the ordered lattice structure is disposed on the secondary electron generating component 10 in the case described above, the lattice structure is not limited to this structure. The lattice structure may be a disordered lattice structure, and is preferably a structure having a broad distribution of lattice size. The advantage of such a structure is that flexibility can be provided in the detection of various defects which cause complicated surface potential distributions.

As a disordered lattice having such a structure, it is possible to conveniently use a grain boundary of a metal film of gold grains which has been formed on a flat substrate by, for example, sputtering and which has a large grain diameter distribution, or a grain boundary of silicon polycrystalline. These grain boundaries may be used to examine the resolution of an ordinary electron microscope, and cause a simple and easy interpretation of an SEM image obtained by such electron microscope.

In order to obtain an extremely broad lattice size distribution, it is preferable to use a crystal grain boundary of an amorphous substance or a crushed surface of a thermally or mechanically crushed thin film. For example, a silicon oxide film used in a semiconductor process is formed on a flat substrate to have a proper thickness. Then the silicon oxide film is intentionally cracked by a rapid temperature change or by the application of a mechanical shock. This crack can be used as the crushed surface. In this case, the broken film is coated with an ion liquid having an extremely high viscosity coefficient to prevent the detachment of the film. Its surface can be suitably used as the detection surface of the secondary electron generating component 10 because the surface of the secondary electron generating component 10 is not charged with electricity even if the electron beam EB is applied thereto. Even when a disordered lattice is used, corresponding positions are easily identified by the superimposition of images.

The above description of the lattice structure of the secondary electron generating component 10 is not limited to the present embodiment, and is also applied to all of the second to sixth embodiments below.

### (2) Embodiment 2

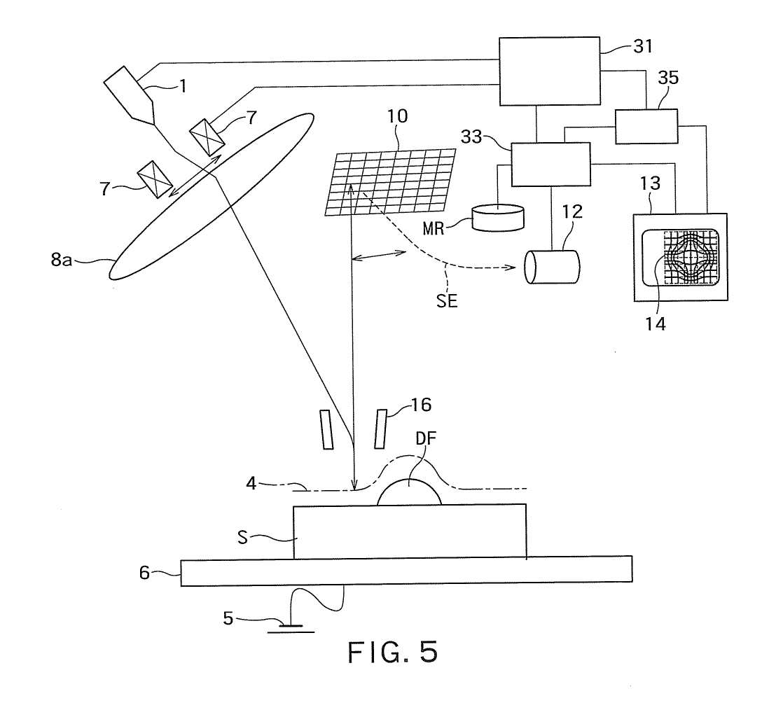

FIG. 5 is a block diagram showing the general configuration of an inspection apparatus according to Embodiment 2. As obvious from the comparison with FIG. 1, the inspection apparatus according to the present embodiment further includes a Wien filter 16 located above the sample S. The secondary electron generating component 10 is located above the Wien filter 16, that is, closer to the electron gun 1 than the Wien filter 16.

The configuration of the inspection apparatus shown in FIG. 5 is substantially the same as that of the inspection apparatus shown in FIG. 1 in other respects. In the present embodiment, the Wien filter 16 corresponds to, for example, an electric field/magnetic field deflector.

In the inspection apparatus according to Embodiment 1, the electron beam EB obliquely enters the sample S. Therefore, the beam flux of the electron beam EB which has been once reduced by, for example, the unshown condenser lens is increased in the equipotential surface 4 again. Unfortunately, the resolution deteriorates accordingly.

Meanwhile, in the inspection apparatus according to the present embodiment, the Wien filter 16 is located above the sample S. The direction of an incoming beam is bent, and then the incoming beam substantially perpendicularly enters the sample S. On the other hand, the electron beam specularly reflected by the equipotential surface 4 enters the secondary electron generating component 10 located just above the equipotential surface 4 without the bending of the locus of this electron beam.

This provides an inspection apparatus with higher resolution.

### (3) Embodiment 3

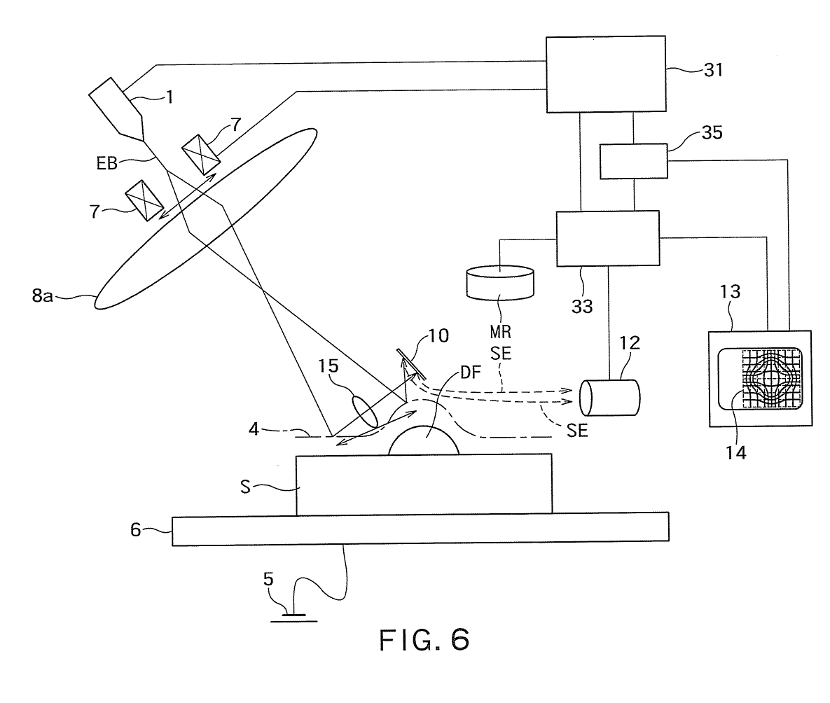

FIG. 6 is a block diagram showing the general configuration of an inspection apparatus according to Embodiment 3. As obvious from the comparison with FIG. 1, the inspection apparatus according to the present embodiment is characterized by further including an electromagnetic lens 15 located between the equipotential surface 4 and the secondary electron generating component 10. The configuration of the inspection apparatus shown in FIG. 6 is substantially the same as that of the inspection apparatus shown in FIG. 1 in other respects.

Thus, in the inspection apparatus according to the present embodiment, the electromagnetic lens 15 is provided closer to the place where the electron beam EB specularly reflected by the equipotential surface 4 enters than the detection surface of the secondary electron generating component 10. As a result, it is possible to appropriately adjust the scanning width on the secondary electron generating component 10 in such a manner that the lattice image on the detection surface of the secondary electron generating component 10 may be observed on the display 13.

Furthermore, as the electromagnetic lens 15 is provided between the equipotential surface 4 and the secondary electron generating component 10, it is possible to improve the degree of freedom in the designing of the distance between the sample S and the secondary electron generating component 10 and the size of a lattice pattern to be fabricated on the secondary electron generating component 10. In order to detect a minute defect, it is necessary that the lattice size of the lattice pattern on the secondary electron generating component 10 should be smaller. In this case, it is preferable to use a magnifying optical system as the electromagnetic lens 15.

### (4) Embodiment 4

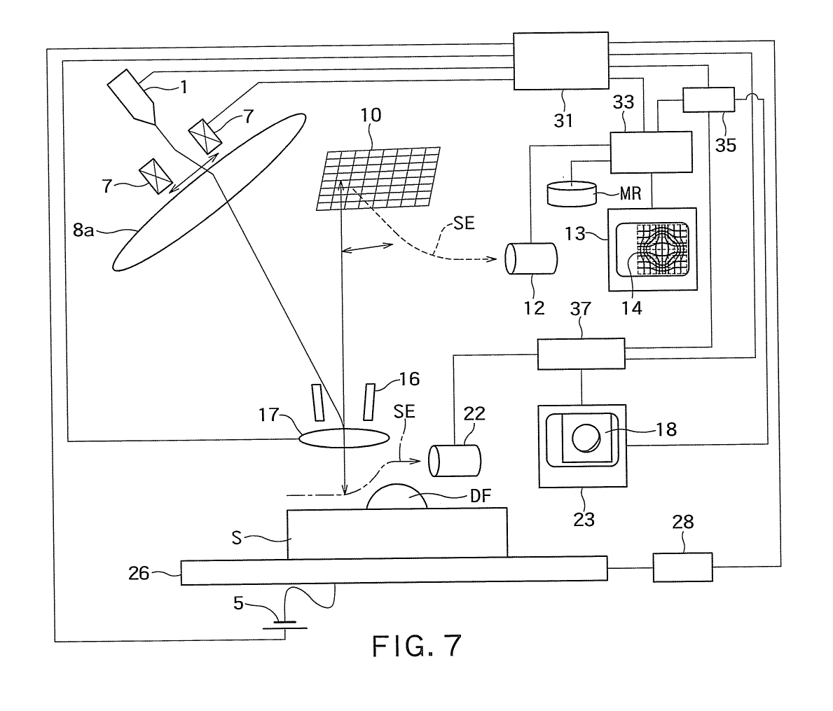

FIG. 7 is a block diagram showing the general configuration of an inspection apparatus according to Embodiment 4. The inspection apparatus according to the present embodiment is configured to be compatible with not only an inspection mode (hereinafter referred to as a “mirror mode”) that uses the lattice image on the secondary electron generating component 10 as in the embodiments described above but also an inspection mode (hereinafter referred to as a “review mode”) that uses a normal high-magnification SEM image. As obvious from the comparison with FIG. 5, an electronic optical system for generating the electron beam EB and applying the electron beam EB to the sample S is common to both the mirror mode and the review mode. Therefore, by the addition of a small number of components, one apparatus permits operations from the acquisition of a surface potential distribution to the classification of defects.

As components added to the configuration in FIG. 5, the inspection apparatus according to the present embodiment further includes an objective lens 17, a secondary electron detector 22, a signal processor 37, and a display 23. The inspection apparatus according to the present embodiment also includes a stage 26 instead of the sample tray 6 in FIG. 5, and a stage driving unit 28 which drives the stage 26. The stage 26 can move the sample S in horizontal two-dimensional directions. In addition, the stage can also move in a vertical direction and in a rotational direction.

In the present embodiment, the objective lens 17, the secondary electron detector 22, the signal processor 37, the display 23, the stage 26, and the stage driving unit 28 correspond to, for example, an SEM image creating unit.

The control unit 31 switches between the mirror mode and the review mode. The control unit 31 is also connected to the objective lens 17, the secondary electron detector 22, the signal processor 37, the display 23, and the stage driving unit 28. The control unit 31 generates a control signal and sends the control signal to these components, and thereby conducts an inspection in the review mode. In the present embodiment, the control unit 31 corresponds to, for example, a mode switching unit.

The inspection apparatus according to the present embodiment first acquires a potential distribution on the surface of the sample S in a broad inspection range by the inspection in the mirror mode as in the first and second embodiments described above, and judges whether the defect DF exists. When the defect DF is judged to exist, the control unit 31 is switched to the review mode.

In the review mode, the control unit 31 first generates a control signal and sends the control signal to the stage driving unit 28, and drives the stage 26 in such a manner that the position where the existence of the defect is recognized comes into view. The control unit 31 then sends the control signal to the voltage source 5, and changes the bias potential of the sample S in such a manner that the electron beam EB is applied to the sample S in a just-focused state.

The control unit 31 then controls the electron gun 1 and the deflection coil 7, and scans the sample S with the electron beam EB at a short deflection width. The secondary electron detector 22 detects the secondary electron SE generated from the surface of the sample S. The signal processor 37 processes the obtained signal to generate a high-magnification SEM image, and sends its data to the defect inspection unit 35. The defect inspection unit 35 classifies and interprets the SEM image to analyze the defect DF, and displays the result on the display 23.

Thus, the inspection apparatus according to the present embodiment enables the acquisition of the surface potential distribution to the analysis of the defects to be continuously performed in one apparatus. Consequently, the turn around time (TAT) of identifying the source of a foreign body is improved.

In contrast with the secondary electron detector 12, the secondary electron detector 22 is preferably located in the vicinity of the objective lens 17 rather than in the vicinity of the secondary electron generating component 10. This improves the yield of secondary electrons from the sample S.

### (5) Embodiment 5

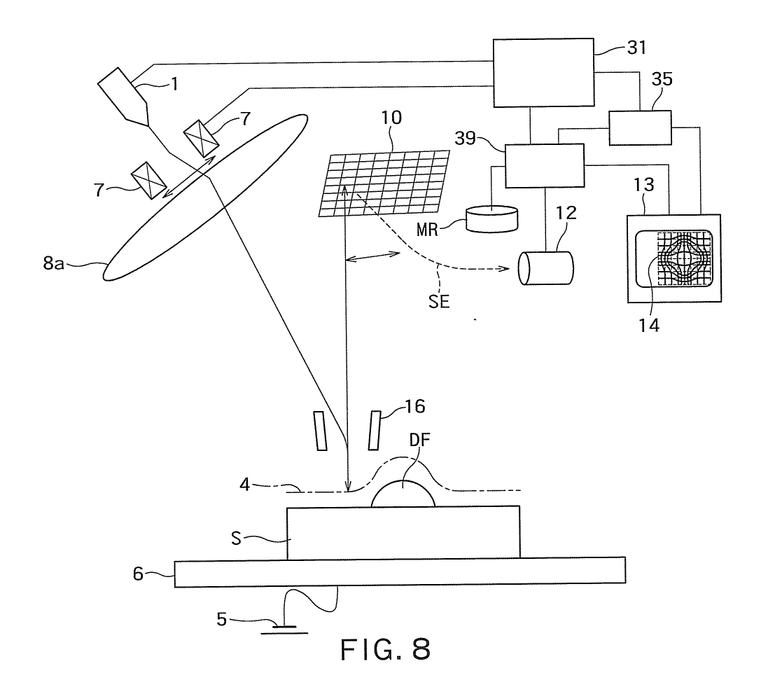

FIG. 8 is a block diagram showing the general configuration of an inspection apparatus according to Embodiment 5. As obvious from the comparison with FIG. 5, the inspection apparatus according to the present embodiment includes a potential distribution acquiring unit 39 instead of the potential distribution acquiring unit 33 shown in FIG. 5. The configuration of the inspection apparatus according to the present embodiment is substantially the same as that of the inspection apparatus shown in FIG. 5 in other respects.

The potential distribution acquiring unit 33 shown in FIG. 5 analyzes, by the optical lever principle, the lattice image obtained by the detection of the secondary electron from the secondary electron generating component 10, and thereby calculates the surface potential gradient in the reflection surface of the electron beam EB. In contrast, the potential distribution acquiring unit 39 provided in the inspection apparatus according to the present embodiment finds the surface potential gradient by fitting a large number of lattice images prepared by a simulation to the actual lattice image obtained from the secondary electron generating component 10.

Since the defect DF includes various shapes and materials, such extreme lattice distortion that the analysis based on the optical lever principle does not necessarily have a unique solution may occur. The inspection apparatus according to the present embodiment can recursively calculate a potential distribution in this case.

The simulative lattice images can be acquired, for example, if various potential distributions in the specular reflection surface on the sample S are generated on a computer and then loci of the electron beam EB applied thereto are calculated. The potential distribution in the sample surface can be calculated by use of an existing method such as a mirror method or an electrification simulation. The simulative lattice images are stored in the memory MR, and extracted by the potential distribution acquiring unit 39 and then used.

In the present embodiment, the actual lattice image corresponds to, for example, a first lattice image, and the simulative lattice image corresponds to, for example, a second lattice image.

### (6) Embodiment 6

FIG. 9 is a block diagram showing the general configuration of an inspection apparatus according to Embodiment 6. As obvious from the comparison with FIG. 7, the inspection apparatus according to the present embodiment is characterized by including a secondary electron generating component 19 instead of the secondary electron generating component 10 in FIG. 7, and further including a motor 21 and a motor driving power source 22.

The secondary electron generating component 19 includes a polyangular column in which lattice patterns having different spaces are formed in the respective surfaces. The secondary electron generating component 19 is supported by a rotation shaft 25 inserted in its central axis. The end of the rotation shaft 25 opposite to the secondary electron generating component 19 side is coupled to the rotation shaft of the motor 21 through the corresponding wall surface of the vacuum chamber 43. The motor 21 is connected to a driving power source 24 and is thus supplied with electric power. The motor 21 is also connected to the control unit 31, and is thus driven in accordance with a control signal sent from the control unit 31. The motor 21 rotates the secondary electron generating component 19 in such a manner that the specularly reflected electron beam EB enters the lattice pattern of a desired surface.

A through-hole in the wall of the vacuum chamber 43 into which the rotation shaft 25 is inserted is sealed with a magnetic fluid seal 20 to keep a high vacuum in the vacuum chamber 43. The configuration of the inspection apparatus according to the present embodiment is substantially the same as that of the inspection apparatus shown in FIG. 7 in other respects.

The inspection apparatus according to the present embodiment allows a side surface in which a desired lattice pattern is formed to be easily selected simply by the rotation of the polyangular column secondary electron generating component 19. Thus, a lattice image having a desired detection resolution can be obtained by a simple apparatus configuration in accordance with the materials, shapes, and sizes of the sample S and the defect DF.

The inspection apparatus according to at least one of the embodiments described above has the substantially flat component which is provided at a position where the electron beam specularly reflected before the sample is focused and in which the lattice pattern is formed. Thus, the potential distribution in the specular reflection surface is acquired from the distorted lattice image which is acquired when the sample surface has a defect or a particle. It is therefore possible to judge with statistical grounds whether the state of the spatial potential distribution is changed by the defect or particle. Consequently, the inspection apparatus capable of accurately detecting troubles in a manufacturing device, processes, and materials is provided.

### (B) Inspection Method

### (1) Embodiment 1

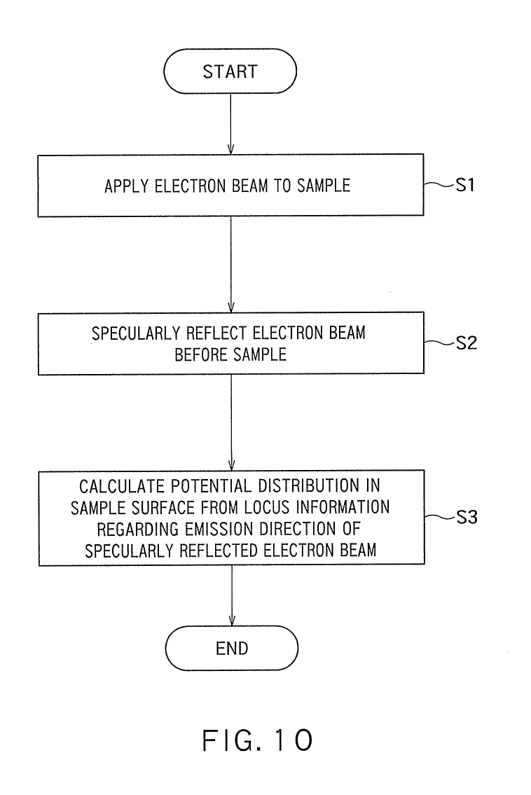

FIG. 10 is a flowchart showing a general procedure of an inspection method according to Embodiment 1.

First, an electron beam (see the electron beam EB in FIG. 1) is applied to a sample S (step S1). A bias voltage which is opposite in polarity to an incoming voltage of the electron beam and which has an absolute value higher than the incoming voltage of the electron beam is applied to the sample S. Thereby, the electron beam is specularly reflected before the sample S (step S2).

Locus information regarding an emission direction of the specularly reflected electron beam is then acquired, and a potential distribution in the surface of the sample S is calculated from the obtained locus information (step S3).

Information regarding the defect of the sample S is then outputted by processing such as image comparison and counting.

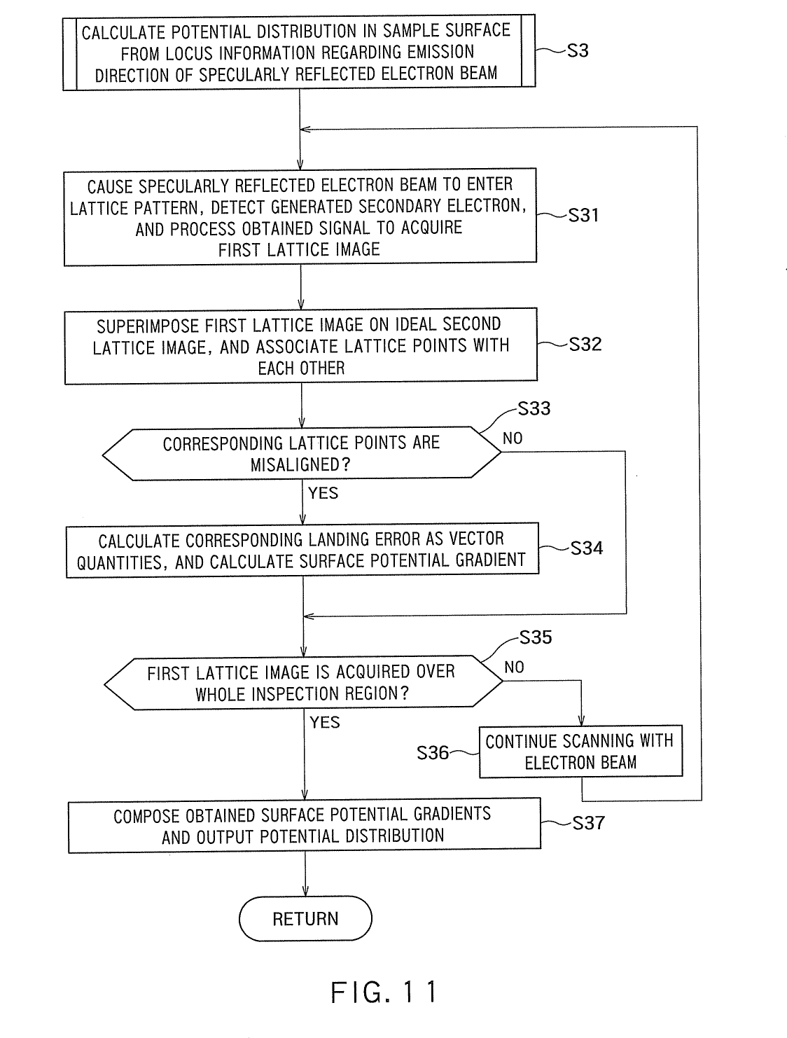

A more specific procedure in step S3 in FIG. 10 is described with reference to a flowchart in FIG. 11.

An arbitrary region on the sample S is scanned with the electron beam. The electron beam is specularly reflected before the sample S and then enters a lattice pattern (see the secondary electron generating component 10 in FIG. 2). A secondary electron generated from the lattice pattern is detected. The obtained signal is processed to acquire a first lattice image which is a lattice image on the lattice pattern (step S31).

The first lattice image obtained in step S31 is superimposed on a second lattice image which is an ideal lattice image on the lattice pattern obtained when the surface of the sample S is flat and when the defect DF (see FIG. 1) resulting from, for example, a foreign matter does not exist. The lattice points of these lattice images are associated with each other (step S32).

Whether the corresponding lattice points are misaligned is then judged (step S33). When there is no misalignment, it is judged that the first lattice image corresponds to the second lattice image and that the defect DF does not exist in this scan region. If there remains another region to be inspected (step S35), this region is scanned (step S36), and the above-mentioned procedures in steps S31 to S34 are repeated.

When there is misalignment, the first lattice image does not correspond to the second lattice image, so that a gradient is generated in the equipotential surface in the specular reflection surface. Therefore, the shift of the landing position in the surface of the lattice pattern caused by the shift of the emission direction of the electron beam reflected due to the gradient is calculated, for example, by use of the optical lever principle. A landing error relative to corresponding positions between the first and second lattice images is calculated as vector quantities. A surface potential gradient resulting from one scan with the electron beam is calculated from the obtained vector quantities (step S34). When there is still an inspection region from which the first lattice image is not acquired (step S35), the next region is scanned (step S36), and the above-mentioned procedures in steps S31 to S34 are repeated.

If surface potential gradients in the respective scans are calculated in the whole inspection region (YES in step S35), the obtained surface potential gradients are composed and outputted as a potential distribution (step S37).

### (2) Embodiment 2

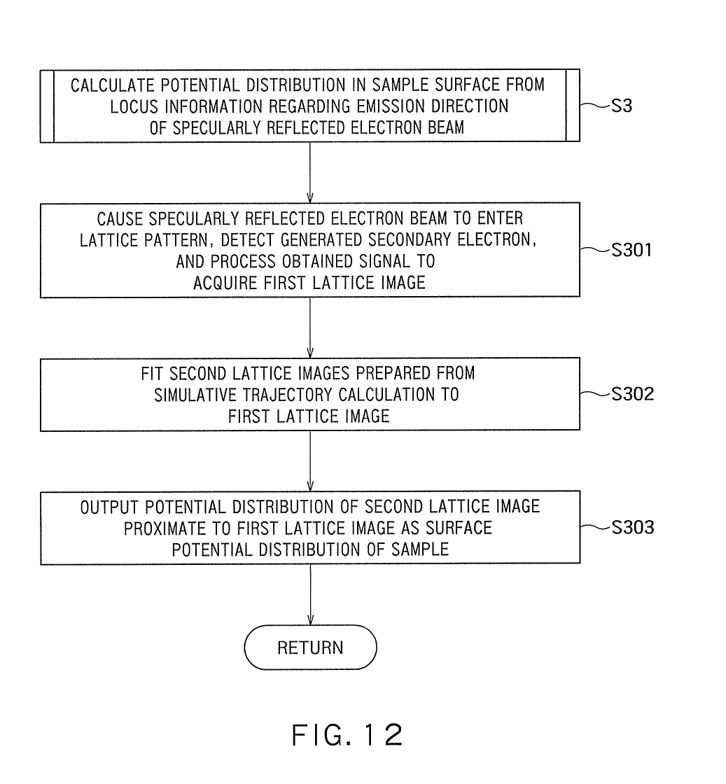

An inspection method according to Embodiment 2 is described with reference to a flowchart in FIG. 12.

The present embodiment is characterized by being different from the first embodiment described above in that the potential distribution in the surface of the sample S is calculated from the locus information regarding the emission direction of the specularly reflected electron beam. The other procedures, that is, the procedures described in steps S1 and S2 in FIG. 10 are the same as those in the first embodiment.

As shown in FIG. 12, the electron beam is specularly reflected before the sample S and enters the lattice pattern (see the secondary electron generating component 10 in FIG. 2). A secondary electron generated from the lattice pattern is detected. The obtained signal is processed to acquire a lattice image on the lattice pattern as a first lattice image (step S301).

A plurality of prepared second lattice images are then acquired from a simulative locus calculation, and the second lattice images are fitted to the first lattice image obtained in step S301 (step S302).

As a result of the fitting, a simulative potential distribution of the second lattice image proximate to the first lattice image is outputted as the surface potential distribution of the sample S (step S303).

The simulative lattice image can be acquired if various potential distributions of the electron beam in the specular reflection surface are generated on a computer and then loci of the electron beam applied thereto are calculated. The potential distribution in the sample surface can be calculated by use of an existing method such as the mirror method or the electrification simulation.

The inspection method according to the present embodiment allows a potential distribution to be recursively calculated in the event of such extreme lattice distortion that the above-mentioned analysis according to Embodiment 1 does not necessarily have a unique solution depending on the shape and material of the defect DF on the sample S.

In the inspection method provided according to at least one of the embodiments described above, the potential distribution in the surface of the sample is calculated from the locus information regarding the emission direction of the specularly reflected electron beam. Therefore, the contrast of the image does not substantially vary with the focus position.

Embodiments will now be explained with reference to the accompanying drawings. Like components are provided with like reference signs throughout the drawings and repeated descriptions thereof are appropriately omitted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions.

For example, although the inspection apparatus according to Embodiment 5 described above includes the potential distribution acquiring unit 39 instead of the potential distribution acquiring unit 33 in the inspection apparatus according to Embodiment 2, this is not a limitation. The potential distribution acquiring unit 39 can also be used instead of the potential distribution acquiring unit 33 in Embodiments 1, 3, 4, and 6. The configuration to obtain the review mode is not exclusively provided in Embodiments 4 and 6, and can be also provided in Embodiments 1, 2, and 5. Moreover, the polyangular column secondary electron generating component 19 and its driving mechanism according to Embodiment 6 are also applicable to any of other Embodiments 1 to 5. Furthermore, various lens systems are mentioned in the above embodiments, however, these lens systems never limit the scope of the present invention. Indeed, specific configurations of the lens systems vary in accordance with various requirements in implementing the invention.

The accompanying claims and their equivalents are intended to cover such forms or modifications as would fall within the scope and spirit of the inventions.

1. An inspection apparatus comprising:
an electron beam applying unit configured to generate an electron beam and apply the electron beam to a sample at a first voltage;
a voltage applying unit configured to apply a second voltage to the sample, a polarity of the second voltage being opposite to that of the first voltage and an absolute value of the second voltage exceeding an absolute value of the first voltage;
a substantially flat component which comprises a lattice pattern and is provided at a position where the electron beam specularly reflected by the second voltage before reaching the sample is focused; and
a first detector configured to detect a secondary electron generated from the component which the specularly reflected electron beam has entered and to output a first signal.

2. The apparatus of claim 1, further comprising:
a potential distribution acquiring unit configured to process the first signal to acquire a potential distribution in a specular reflection surface on which the electron beam is specularly reflected.

3. The apparatus of claim 2,
wherein the potential distribution acquiring unit acquires a first lattice image of the component, associates lattice points between the first lattice image and an ideal second lattice image which is obtained when an equipotential surface in the specular reflection surface is a plane parallel to the surface of the sample, finds a landing error of the electron beam resulting from a local potential gradient in the specular reflection surface when the corresponding lattice points are misaligned, calculates potential gradients in the specular reflection surface from the obtained landing error, and composes the potential gradients to acquire the potential distribution.

4. The apparatus of claim 1,
wherein the lattice pattern of the component is disordered.

5. The apparatus of claim 2,
wherein the potential distribution acquiring unit acquires a first lattice image of the component, fits the first lattice image to a plurality of second lattice images prepared from a simulative locus calculation, and outputs a simulative potential distribution of the second lattice image proximate to the first lattice image as the potential distribution in the specular reflection surface.

6. The apparatus of claim 1, further comprising:
an electromagnetic lens provided between a surface in which the electron beam is specularly reflected and the component.

7. The apparatus of claim 1, further comprising:
an objective lens configured to control a focus position of the electron beam in such a manner that the electron beam is just focused on the sample;
a second detector provided between the objective lens and the sample and configured to detect a secondary electron reflected from the sample and output a second signal;
an SEM image creating unit configured to process the second signal to create an SEM image; and
a mode switching unit configured to switch between a mirror mode and a review SEM mode.

8. The apparatus of claim 1,
wherein the component comprises a polyhedron in which a plurality of different lattice patterns are formed in the respective surfaces.

9. The apparatus of claim 8,
wherein the lattice patterns comprise different lattice spaces, respectively.

10. The apparatus of claim 8, further comprising:
a driving unit configured to rotate the component to switch the lattice patterns.

11. An inspection apparatus comprising:
an electron beam applying unit configured to generate an electron beam and obliquely apply the electron beam to a sample at a first voltage;
a voltage applying unit configured to apply a second voltage to the sample, a polarity of the second voltage being opposite to that of the first voltage and an absolute value of the second voltage exceeding an absolute value of the first voltage;
a substantially flat component which comprises a lattice pattern and is provided at a position where the electron beam specularly reflected by the second voltage before reaching the sample is focused;
a first detector configured to detect a secondary electron generated from the component which the specularly reflected electron beam has entered and to output a first signal;
a potential distribution acquiring unit configured to process the first signal to acquire a potential distribution in a specular reflection surface on which the electron beam is specularly reflected; and
an electric field/magnetic field deflector located between the electron beam applying unit and the sample and configured to control a locus of the electron beam so as to make the electron beam from the electron beam applying unit emit in a direction substantially perpendicular to the sample and so as to make the electron beam from the sample emit straight,
wherein the component is located closer to the electron beam applying unit than the electric field/magnetic field deflector.

12. An inspection method comprising:
generating an electron beam and applying the electron beam to a sample at a first voltage;
applying a second voltage to the sample, a polarity of the second voltage being opposite to that of the first voltage and an absolute value of the second voltage exceeding an absolute value of the first voltage;
acquiring locus information regarding an emission direction of the electron beam specularly reflected by the second voltage before reaching the sample; and
calculating a potential distribution in the surface of the sample from the locus information.

13. The method of claim 12,
wherein the locus information is obtained by calculating a landing position of the electron beam at a position where the electron beam is focused.

14. The method of claim 12,
wherein acquiring the potential distribution comprises causing the electron beam to enter a lattice pattern at a position where the electron beam is focused, processing a first signal obtained by detecting a generated secondary electron to acquire a first lattice image at the focus position, associating lattice points between the first lattice image and an ideal second lattice image which is obtained when an equipotential surface in the specular reflection surface is a plane, finding a landing error of the electron beam resulting from a local potential gradient in the specular reflection surface when the corresponding lattice points are misaligned, and calculating potential gradients in the specular reflection surface from the obtained landing error.

15. The method of claim 14,
wherein the potential distribution is acquired by composing the obtained potential gradients.

16. The method of claim 14, further comprising:
forming an electric field or a magnetic field between a surface in which the electron beam is specularly reflected and the component, and adjusting a scanning width on the lattice pattern.

17. The method of claim 12, further comprising:
switching between a mirror mode and a review SEM mode,
wherein in the review SEM mode, a focus position of the electron beam is controlled in such a manner that the electron beam is just focused on the sample,
the method further comprising detecting a secondary electron reflected from the sample, and processing an obtained second signal to create an SEM image.

18. The method of claim 14, further comprising:
switching a plurality of kinds of lattice patterns.

19. The method of claim 12,
wherein a locus of the electron beam is controlled in such a manner that the electron beam travels in a direction substantially perpendicular to the sample after obliquely emitted toward the sample,
a locus of the specularly reflected electron beam is controlled in such a manner that the electron beam travels straight.

20. The method of claim 12,
wherein acquiring the potential distribution comprises causing the electron beam to enter a lattice pattern at a position where the electron beam is focused, processing a first signal obtained by detecting a generated secondary electron to acquire a first lattice image at the focus position, fitting the first lattice image to a second lattice image prepared from a simulative locus calculation, and outputting a simulative potential distribution of the second lattice image proximate to the first lattice image as the potential distribution in the specular reflection surface.
